(19) United States
(12) Patent Application Publication
(10) Pub. No.: US 2006/0139041 A1
(43) Pub. Date: Jun. 29, 2006

(54) System and method of testing and utilizing a fluid stream

(76) Inventors: Michael James Nystrom, San Jose, CA (US); Bill James Peck, Mountain View, CA (US); William Gary Chesk, San Jose, CA (US)

Correspondence Address: AGILENT TECHNOLOGIES, INC.;INTELLECTUAL PROPERTY ADMINISTRATION, LEGAL DEPT., P.O. BOX 7599, M/S DL429, LOVELAND, CO, 80537-0599, US

(21) Appl. No.: 11/021,602

(22) Filed: Dec. 23, 2004

(51) Int. Cl. G01R 31/02

(52) U.S. Cl. 324/754

(57) ABSTRACT

There are disclosed systems and methods in which a liquid dispensing head is positioned above the contact area of the device under test (DUT). A stream of liquid is dispensed from the head such that a continuous column of liquid extends from the head to the contact area of the test device. This column of liquid completes a circuit which allows current to flow thereby allowing for current measurement.

### CROSS-REFERENCE TO RELATED APPLICATIONS

The present application is related to concurrently filed, co-pending, and commonly assigned U.S. patent application Ser. No. ______, Attorney Docket No. 10041037-1, entitled “NON-CONTACT ELECTRICAL PROBE UTILIZING CHARGED FLUID DROPLETS,” and U.S. patent application Ser. No. ______, Attorney Docket No. 10041087-1, entitled “SYSTEMS AND METHODS FOR AN ELECTRICAL PROBING MEDIUM USING AN IONIZED GAS CREATED BY AN ATMOSPHERIC DISCHARGE,” the disclosures of which are hereby incorporated herein by reference.

### BACKGROUND OF THE INVENTION

Organic light emitting diode (OLED) flat panel displays use an emissive flat panel display technology that is an extension of the existing thin film transistor (TFT) liquid crystal display (LCD) technology. While OLED technology is similar to TFT technology, the emissive property of the OLED displays leads to greater complexity, particularly for testing during manufacturing. One difference, as it applies to testing, is that the OLED pixel brightness is controlled with a current signal, as opposed to being controlled with a voltage as are existing LCD displays. This results in the OLED display having one additional transistor per pixel.

To test existing LCD displays, the voltage controlling each pixel can be directly measured even without touching the active area of the display's surface. However, in order to test each pixel of the OLED display, it is necessary to measure current on the display at each pixel also without actually touching the display surface.

While, several techniques are known to sense voltage without actually touching the surface, current sensing without touching presents a problem. For example, voltage can be sensed by using an electron beam to image the surface, such that, voltage differences on the surface show as contrast differences. One technique to measure current is to incorporate an additional capacitor per pixel on the OLED display circuit and to measure the charging of this added capacitor through a resistor. This works because the charging rate of the capacitor is a direct function of the resistance value of the resistor. This technique adds complexity to the circuitry and adds a component that will not be used again after testing.

A second technique is to use an electron beam as a contactless probe. This technique requires placing the OLED in a vacuum chamber which is expense and time consuming.

### BRIEF SUMMARY OF THE INVENTION

There are disclosed systems and methods in accordance with the invention in which a liquid dispensing head is positioned above the contact area of the device under test (DUT). A stream of liquid is dispensed from the head such that a continuous column of liquid extends from the head to the contact area of the test device. This column of liquid completes a circuit which allows current to flow thereby allowing for current measurement. In this manner, for example, the transistor at each pixel of an OLED can be tested.

### BRIEF DESCRIPTION OF THE DRAWINGS

For a more complete understanding of the present invention, reference is now made to the following descriptions taken in conjunction with the accompanying drawing, in which:

FIG. 1 shows one embodiment of a test system in accordance with the invention; and

FIG. 2 shows one embodiment of a test system in accordance with the invention.

### DETAILED DESCRIPTION OF THE INVENTION

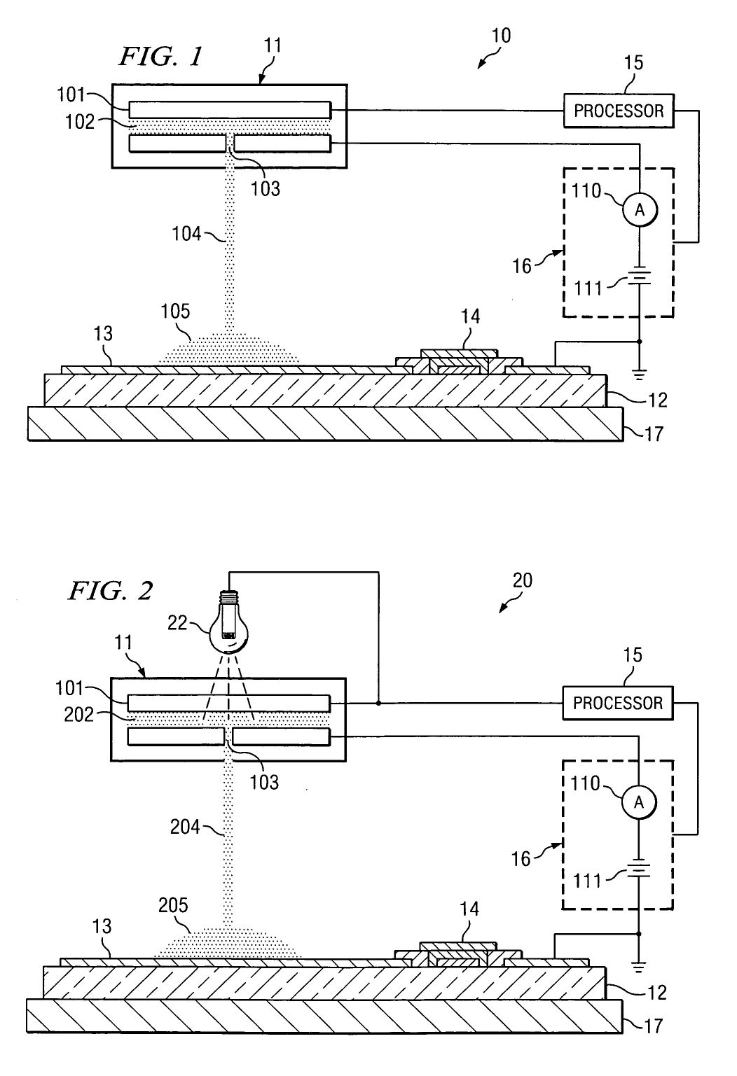

FIG. 1 shows one embodiment of test system 10 in accordance with the invention where test head 1 1 selectively allows fluid 102 to flow therefrom to form a pool of fluid 105 on a contact pad, such as on contact pad 13, of DUT 12. Contact pad is in contact with device 14 to be tested (in this case the device is a transistor which is part of DUT 12), DUT 12 can be, for example, an OLED display panel or any other device that must be tested without direct physical contact. Display panel 12, in turn, rests in this embodiment on test bed 17, which can be any type of test bed. In other embodiments display panel 12 can be self-supporting, if desired.

Test head 11 in the embodiment shown is a piezoelectric inkjet head having control element 101, fluid 102, and control orifice 103, which selectively allows fluid 102 to flow which result in pool of fluid 105 on contact 13. Fluid 102 is a conductive fluid so that it forms a continuous electric path from test head 11 to contact pad 13. The fluid must also be easy to clean from the contact pad after the measurement. An ionic conductor would be acceptable as would water with ionic impurities or perhaps mercury or other elements that are conductive but that also have the properties of water. Neither the fluid nor the impurities must react with the contact pad surface and must be readily removed from the surface after the test.

Conductive fluid 104 would complete an electrical path from voltage source 111 through meter 110, head 11, fluid pool 105, and transistor 14 to ground, thereby allowing for the measurement of current flow through transistor 14 of OLED 12. A processor, such as processor 15, could control both the application of the current as well as the flow of the liquid such that the liquid can be selectively controlled, if desired. Note that processor 15 could be part of control 16 or could be separate therefrom, or can be part of test head 11, if desired. The system could be adapted to measure voltage instead of current, if desired, all without the test probe touching the surface of the DUT.

When the test of display panel 12 is complete, the conductive liquid is stopped; the liquid in pool 105 is wiped clean from the surface, the panel is removed, and another panel inserted in its place. Note that in the embodiment, it is contemplated that test head 11 and test bed 17, as well as the circuitry that controls the test fixture, is permanently in place. Alternatively, the system can be hand held such that the test head is part of a portable device, such that liquid can be squirted from the head to the display to complete a circuit for the purpose of measuring current flow between the test head and the device under test.

In device 10 liquid stream 104 is shown falling by gravity from head 11. However, liquid can be under power and controlled by head 11 or by orifice 103 which can operate much like a squeeze bottle to pulse liquid through orifice 103 in a steady stream. For horizontal operation this might be preferable. Orifice 103 could be arranged to selectively direct the liquid stream, if desired.

FIG. 2 shows the same DUT 12 as shown in FIG. 1 except that in the embodiment of FIG. 2 test system 20 uses fluid 202 falling in stream 204 to pool 205. Fluid 202 is nonconductive (or of low conductivity) as it emerges from head 11 until such time as energy from an external energy source, such as energy source 22, impacts stream 204. In the embodiment, energy source 22 is light, impacting fluid 202, which charges the fluid making it conductive only while energy source 22 is on. Energy source 22 could be light or any other type of energy source, such as ultraviolet, infrared, etc. Using this arrangement, movement of the uncharged fluid (light off) across panel 12 will not interact with the electronics except when desired. One problem that a conductive fluid would encounter is the shorting of electronics on the DUT. When the pool of liquid on the surface spreads, multiple devices can become shorted together, making the measurement difficult or impossible. If the fluid is selectively conductive, only the fluid that is receiving external energy (which can be precisely focused) would be conductive, and thus, the liquid pool will not cause problems with the electronics. This allows much more fluid to be used to make a connection between the head and the panel. If more fluid can be used, the distance between the inkjet head and panel can be increased. It is contemplated that the distance between orifice 103 and contact 13 will be approximately 100 microns.

Note that while the disclosure has been framed in context to testing an OLED panel, the concepts discussed herein could be used to test any device without actually touching that device.

Also, it should be understood that while a single aperture is shown forming a single column, a plurality of apertures could be used to control multiple columns, or a single aperture could be used to direct the droplets to different contact locations.

Although the present invention and its advantages have been described in detail, it should be understood that various changes, substitutions and alterations can be made herein without departing from the invention as defined by the appended claims. Moreover, the scope of the present application is not intended to be limited to the particular embodiments of the process, machine, manufacture, composition of matter, means, methods and steps described in the specification. As one will readily appreciate from the disclosure, processes, machines, manufacture, compositions of matter, means, methods, or steps, presently existing or later to be developed that perform substantially the same function or achieve substantially the same result as the corresponding embodiments described herein may be utilized. Accordingly, the appended claims are intended to include within their scope such processes, machines, manufacture, compositions of matter, means, methods, or steps.

What is claimed is:

1. A probe comprising:
a liquid dispensing head adapted for being disposed apart from an electrical contact area; and
said dispensing head having at least one input for receiving an electrical signal to be communicated to said contact area through said liquid when said liquid spans a gap between said dispensing head and said contact area.

2. The probe of claim 1 wherein said liquid is conductive.

3. The probe of claim 1 wherein said liquid is selectively conductive.

4. The probe of claim 3 further comprising:
a source of energy to selectively control said conductivity of said liquid.

5. The probe of claim 4 wherein said energy is in the light spectrum.

6. The probe of claim 1 wherein said probe further comprises:
at least one input for controlling the dispensing of said liquid.

7. The probe of claim 1 wherein said liquid is water with ionic impurities therein.

8. A method of testing an organic light emitting diode (OLED), said method comprising:
establishing a conductive liquid path between a test probe and a contact area of said OLED; and
passing current between said test probe and said contact area using said established conductive liquid path.

9. The method of claim 8 wherein said establishing comprises:
selectively supplying external radiation to liquid flowing between said test probe and said contact area.

10. A test device comprising:
means for providing test signals;
means for positioning a device under test (DUT); and
means spaced apart from said positioning means for selectively controlling the flow of material therefrom, said selectively controlling means having at least one aperture in line with at least one contact area of a positioned DUT so as to allow said material to complete an electrical circuit for the passage of said test signals.

11. The test device of claim 10 further comprising:
means for controlling test procedures among said test signal source, said spaced apart means and a DUT.

12. The test device of claim 11 wherein said test procedures comprise:
means for enabling said selectively controlling means.

13. The test device of claim 10 further comprising:
means for selectively controlling the conductivity of material flowing from said aperture.

14. The test device of claim 13 wherein said conductivity controlling means comprises:
means for providing radiant energy for changing the conductivity of said flowing material.

15. The test device of claim 10 wherein said flowing material is electrically conductive.

16. The test device of claim 10 wherein said material flows from said test probe by the force of gravity.

17. The test device of claim 10 wherein said material is forcibly ejected from said test probe.

18. The test device of claim 10 wherein said test probe comprises:
an inkjet head.

19. The test device of claim 18 wherein said inkjet head comprises:
a piezoelectric inkjet head.

20. The test device of claim 10 wherein said DUT is an OLED.
